(19) United States
(12) Patent Application Publication
(10) Pub. No.: US 2025/0006470 A1
(43) Pub. Date: Jan. 2, 2025

(54) EDGE CAPACITIVELY COUPLED PLASMA CHAMBER STRUCTURE

(71) Applicant: Lam Research Corporation, Fremont, CA (US)

(72) Inventors: Alexei Marakhtanov, Albany, CA (US); Bing Ji, Pleasanton, CA (US); Kenneth Lucchesi, Newark, CA (US); John Holland, San Jose, CA (US)

(21) Appl. No.: 18/694,949

(22) PCT Filed: Sep. 28, 2022
(86) PCT No.: PCT/US2022/045090

§ 371 Date: Mar. 22, 2024

Related U.S. Application Data
(60) Provisional application No. 63/250,094, filed on Sep. 29, 2021.

(51) Int. Cl. H01J 37/32

(52) U.S. Cl. CPC H01J 37/32541; H01J 37/32091; H01J 37/32174; H01J 37/32568; H01J 37/32577; H01J 37/32642

(57) ABSTRACT

An outer upper electrode for a capacitively coupled plasma (CCP) chamber is provided. The outer upper electrode is configured to surround an upper electrode of the CCP chamber. The outer upper electrode includes a horizontal section and a vertical section. The vertical section is substantially perpendicular to a surface of the upper electrode that faces a lower electrode of the CCP chamber. The vertical section has an inner surface that faces and surrounds the process space. The outer upper electrode can be powered with an RF source, a DC source, or coupled to filters. The outer upper electrode, when powered, is configured to generate secondary electrons that are accelerated in the high voltage RF or DC sheath transverse to the upper and lower electrodes and normal to an inner surface of the vertical section.

### FIELD OF THE DISCLOSURE

The present disclosure relates to semiconductor device fabrication.

### DESCRIPTION OF THE RELATED ART

Plasma etching processes are often used in the manufacture of semiconductor devices on semiconductor wafers. In the plasma etching process, a semiconductor wafer that includes semiconductor devices under manufacture is exposed to a plasma generated within a plasma processing volume. The plasma interacts with material(s) on the semiconductor wafer so as to remove material(s) from the semiconductor wafer and/or modify material(s) to enable their subsequent removal from the semiconductor wafer. The plasma can be generated using specific reactant gases that will cause constituents of the plasma to interact with the material(s) to be removed/modified from the semiconductor wafer, without significantly interacting with other materials on the wafer that are not to be removed/modified. The plasma is generated by using radiofrequency signals to energize the specific reactant gases. These radiofrequency signals are transmitted through the plasma processing volume that contains the reactant gases, with the semiconductor wafer held in exposure to the plasma processing volume.

The transmission paths of the radiofrequency signals through the plasma processing volume can affect how the plasma is generated within the plasma processing volume. For example, the reactant gases may be energized to a greater extent in regions of the plasma processing volume where larger amounts of radiofrequency signal power is transmitted, thereby causing spatial non-uniformities in the plasma characteristics throughout the plasma processing volume. The spatial non-uniformities in plasma characteristics can manifest as spatial non-uniformity in ion density, ion energy, and/or reactive constituent density, among other plasma characteristics. The spatial non-uniformities in plasma characteristics can correspondingly cause spatial non-uniformities in plasma processing results on the semiconductor wafer.

There is a need for structures and systems that enable additional control of the way power is delivered to the chamber, and in turn assist in reducing spatial non-uniformities. It is within this context that the present disclosure arises.

### SUMMARY

The embodiments disclosed herein provide for new configuration of a capacitive coupled plasma source with additional plasma generation by transverse electron beam of secondary electrons parallel to wafer surface. The electron beam is generated in the high voltage RF or DC plasma sheath at an inner peripheral region of a vertical section of an L-shaped electrode. The L-shaped electrode is an outer upper electrode that is powered independently of power supplied to the lower electrode. When the L-shape of the outer upper electrode is installed, the L-shape is upside-down to allow the vertical section to hang downward in a direction that is toward a lower part of a C-shroud. In one embodiment, outer upper electrode can be powered and used as an independent knob to control plasma properties above the wafer. Typically, capacitive coupled plasma (CCP) chambers generate plasmas generated between two parallel flat electrodes, with limited independent control of plasma parameters. For example, small changes in RF power lead to changes in RF current through the plasma and changes of RF sheath voltage which results in the change of ion flux to wafer and ion energy. Another issue with current CCP chambers is that plasma losses at the plasma periphery cannot generally be controlled easily and typically set by a physical barrier, such as a C-shroud wall. Less control also leads to loss of plasma species at the edge of the wafer.

In one embodiment, the structure disclosed herein is designed to increase power efficiency/density and chemistry control/uniformity by controlling a transverse beam of electrons. The structure provides edge power to an L-shaped electrode to form an edge CCP configuration. The transverse beam of electrons is generated between a plasma sheath formed in the vertical section of the L-shaped electrode. The L-shaped electrode is coupled to one of a direct current (DC) power source, and RF power source, filter circuits, or a combination of filter circuits and DC or RF power sources. The plasma sheath formed to produce the transverse beam of electrons, in one embodiment, is in addition to the plasma sheath generated between the RF powered lower electrode and grounded upper electrode. In some configurations, the upper electrode may also be connected to an RF source and/or a filter circuit.

In one embodiment, secondary electrons are accelerated in the high voltage 400 kHz or DC sheath at the vertical wall of the L-shaped electrode and will travel across the plasma increasing efficiency of RF discharge. In still another embodiment, power is provided to the L-shaped electrode, e.g., to provide edge power and a transverse electron beam as the main RF power (i.e., without supplying power to the lower or upper electrode). This configuration can be used to create low ion energy plasma as dual or triple frequency capacitively coupled plasmas (CCPs) are mainly generated by stochastic heating from oscillations of high frequency RF sheath and ionization by secondary electrons produced by high voltage low frequency sheaths. In still another embodiment, secondary electrons travel in a direction perpendicular to CCP plasma electrodes, i.e., parallel plates. As a further advantage, a configuration that uses the L-shaped electrode offers control of an independent source of transverse secondary electrons that will enhance the plasma above the wafer and will provide independent knob for control. In some configurations, the embodiments disclosed herein may also be used for low ion energy plasma applications by using edge power only (i.e., only providing power to the L-shaped electrode), which have added applications in atomic layer deposition (ALD) and/or atomic layer etching (ALE).

In an example embodiment, a capacitively coupled plasma (CCP) chamber that includes a lower electrode and an upper electrode is disclosed. The CCP chamber includes a shroud arranged to surround a process space between the upper electrode and the lower electrode. Further included is an outer upper electrode arranged to surround the upper electrode. The outer upper electrode includes a horizontal section and a vertical section. The vertical section is substantially perpendicular to a surface of the upper electrode that faces the lower electrode. The vertical section has an inner surface that faces and surrounds the process space.

In another example embodiment, an outer upper electrode for a capacitively coupled plasma (CCP) chamber is provided. The outer upper electrode is configured to surround an upper electrode of the CCP chamber. The outer upper electrode includes a horizontal section and a vertical section. The vertical section is substantially perpendicular to a surface of the upper electrode that faces a lower electrode of the CCP chamber. The vertical section has an inner surface that faces and surrounds the process space.

In one configuration, the outer upper electrode, i.e., L-shaped electrode is a consumable part made of polysilicon. As the system is used, the outer upper electrode may be consumed and at some point, will need to be replaced with a new L-shaped electrode.

### BRIEF DESCRIPTION OF THE DRAWINGS

FIG. 1 shows a plasma processing system that includes an upper outer electrode that surrounds the upper electrode, in accordance with one embodiment.

FIGS. 2A-2C illustrate more detailed views of the outer upper electrode, in accordance with one embodiment.

FIGS. 2D-1 and 2D-2 illustrate closer views of the connections between a connector ring and the outer upper electrode 120, in accordance with one embodiment.

FIGS. 2E-1 and 2E-2 illustrate top views of a connector ring and the outer upper electrode and connections to power rods, in accordance with one embodiment.

FIG. 3 illustrates an example configuration of a semiconductor processing chamber having the outer upper electrode with the vertical section, in accordance with one embodiment.

FIG. 4 illustrates an embodiment where a direct current (DC) voltage source is coupled to a connection node, for providing DC power to the outer upper electrode, in accordance with one embodiment.

FIG. 5 illustrates an embodiment where a filter circuit is connected to the connection node, and no power source is connected to the connection node, in accordance with one embodiment.

FIG. 6A illustrates an embodiment where connection node is coupled to an RF source and match, for providing RF power to the outer upper electrode via power rods, in accordance with one embodiment.

FIG. 6B illustrates an embodiment where the RF sources are frequency locked and phase controlled, in accordance with one embodiment.

FIG. 7 illustrates an embodiment where connection node is connected to a variable impedance circuit, in accordance with one embodiment.

FIG. 8 shows an example schematic of a control system, in accordance with some embodiments.

### DETAILED DESCRIPTION

In the following description, numerous specific details are set forth in order to provide an understanding of embodiments of the present disclosure. It will be apparent, however, to one skilled in the art that embodiments of the present disclosure may be practiced without some or all of these specific details. In other instances, well known process operations have not been described in detail in order not to unnecessarily obscure the present disclosure.

Broadly speaking, this disclosure provides for an additional outer upper electrode that includes a vertical section. The vertical section is annular and is configured to partially surround a process region between the upper electrode and lower electrode of a CCP chamber. In one embodiment, the vertical section is integrally coupled to a horizontal section for forming an L-shaped annular structure. The vertical section of the outer upper electrode may be powered by an RF source or DC source, and/or coupled to filters. In operation, the outer upper electrode may be powered to represent an additional capacitive coupled plasma (CCP) source that produces a plasma sheath along the inner surface of the vertical section of the L-shaped structure. The plasma generated by the plasma sheath provides a transverse electron beam of secondary electrons parallel to wafer surface.

In one specific example, the electron beam is generated in the high voltage RF or DC plasma sheath at an inner peripheral region of a vertical section of an L-shaped electrode. The L-shaped electrode is an outer upper electrode that is powered independently of power supplied to the lower electrode. In one embodiment, an outer upper electrode can be powered and used as independent knob to control plasma properties above wafer.

Some example benefits of the disclosed configuration of the L-shaped electrode is the ability to increase density and improve etch rate, increased uniformity out to the edge of the wafer, increased efficiency out to the edge of the wafer, increased electrons to control chemistry reactions, and powering only the L-shaped electrode to produce plasmas with low ion energy for use in ALD and ALE applications. With this overview in mind, the following figures illustrate example structures that can be implemented to construct systems that include the L-shaped electrode in the chamber process volume.

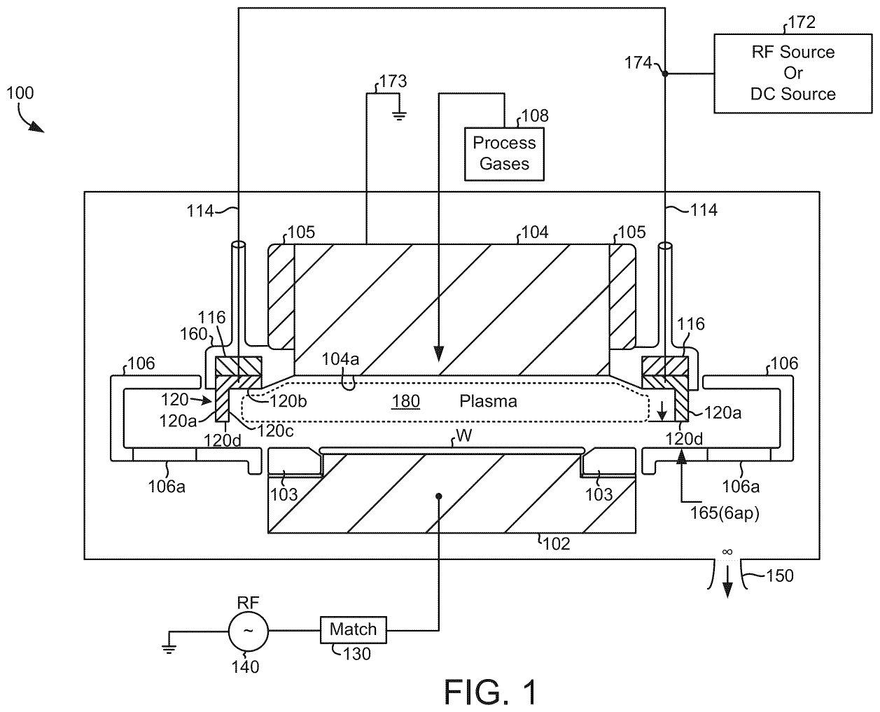

FIG. 1 shows a plasma processing system 100 that includes an upper outer electrode 120 that surrounds the upper electrode 104. The outer upper electrode 120 is, in one embodiment, made of a polysilicon material. The upper electrode 104 is disposed opposite the lower electrode 102. A shroud 106 having a C-shape, also known as a C-shroud surrounds the processing volume where plasma 180 is generated. The C-shroud 106 is in one embodiment made of a polysilicon material. The shroud 106 provides a shape that enables the processing volume to expand outward from between the upper electrode 104 and lower electrode 102. The shroud 106 also includes a plurality of slots 106a that are usable for venting the processing volume. The slots 106a are usually less than 5 mm or less than 3 mm to prevent plasma ignition below the slots 106a. The slots 106a may have any number of shapes, e.g., elongated slots, short slots, circular holes, holes, etc. In one example embodiment, the slot dimension of slots 106a are about 2 mm in width and about 7.4 mm depth (i.e., thickness of the C-shroud wall).

In this configuration, an edge ring 103 is disposed to surround a surface over the lower electrode 102 where a wafer (W) is placed for processing. It should be understood that other structural configurations may be provided to define the lower electrode 102, such as insulator rings, cooling channels in the lower electrode 102, lift pins, chucking electrodes, and the like. The plasma processing system 100 also includes one or more vacuum ports 150, for evacuating gases during operation.

In one configuration, the lower electrode 102 is connected to radio frequency (RF) power source 140, via a match 130. The RF power source 140 may operate at frequencies such as 13.56 MHz, 60 MHz, 27 MHz, 2 MHz, 400 kHz. In some embodiments, the RF power source 140 may be one of multiple RF power sources that may simultaneously operate at different frequencies. In one embodiment, the upper electrode 104 may be connected to ground 173.

In other configurations, the upper electrode may be connected to one or more RF power sources operating at one or more of the above-identified frequencies. Specifically, in some configurations, the lower electrode 102 is grounded instead of the upper electrode 104 and the upper electrode 104 is connected to an RF power source, such as RF generator 140.

The frequencies identified in these examples should be viewed as approximate and may vary depending on the process recipe being applied during processing of a specific wafer. The plasma processing system 100 is also shown to be connected to process gases 108, which are channeled into the process space between the upper electrode 104 and the lower electrode 102.

In accordance with one embodiment, the upper outer electrode 120 is electrically connected to an RF source or direct current (DC) source 172. The upper outer electrode 120 may also be connected to a filter and or ground, depending on the type of control required for affecting the plasma in the processing region. In one embodiment, the upper outer electrode 120 is defined by two sections, namely a vertical section 120a and a horizontal section 120b. The vertical section 120a and the horizontal section 120b are joined at an outside corner to form an L-shape, where the vertical section 120b extends downward away from the horizontal section 120b, and toward a horizontal section of the shroud 106. In one embodiment, the L-shaped structure of the outer upper electrode 120 is contained within the process volume and separates the main process volume between the upper electrode 104 and the lower electrode 102 from an outer annular region defined by the C-shroud 106. In one embodiment, the outer annular region of the C-shroud 106 is between the vertical section 102a, the inside surface of the outer wall of the C-shroud 106, the inner surface of the upper wall of the C-shroud 106, and the plurality of slots 106a of the C-shroud 106.

As shown, a gap 165 is defined between an inner surface of the shroud 106 proximate to the plurality of slots 106a and a lower end 120d of the vertical section 120a. With this configuration, the vertical section 120a will provide an inner facing surface 120c which is substantially perpendicular to a surface of the lower electrode 102 and a surface of the upper electrode 104. The inner facing surface 120c of the outer upper electrode 120 will therefore provide for the formation of a plasma sheath that enables a transverse beam of electrons to be generated between a plasma sheath formed in the vertical section 120a of the outer upper electrode 120 (e.g., the L-shaped electrode).

In one configuration, the outer upper electrode 120 is electrically coupled to the RF source or DC source 172, via a plurality of power rods 114. The plurality of power rods 114 are electrically connected together, and are therefore able to be connected to the RF source or DC source 172 via a connection node 174. An electrode insulator 160 is shown to surround the power rods 114, and a connector ring 116 is shown electrically coupled to the outer upper electrode 120. An insulator 105 is also provided to insulate the upper electrode 104 from other parts in the upper electrode region.

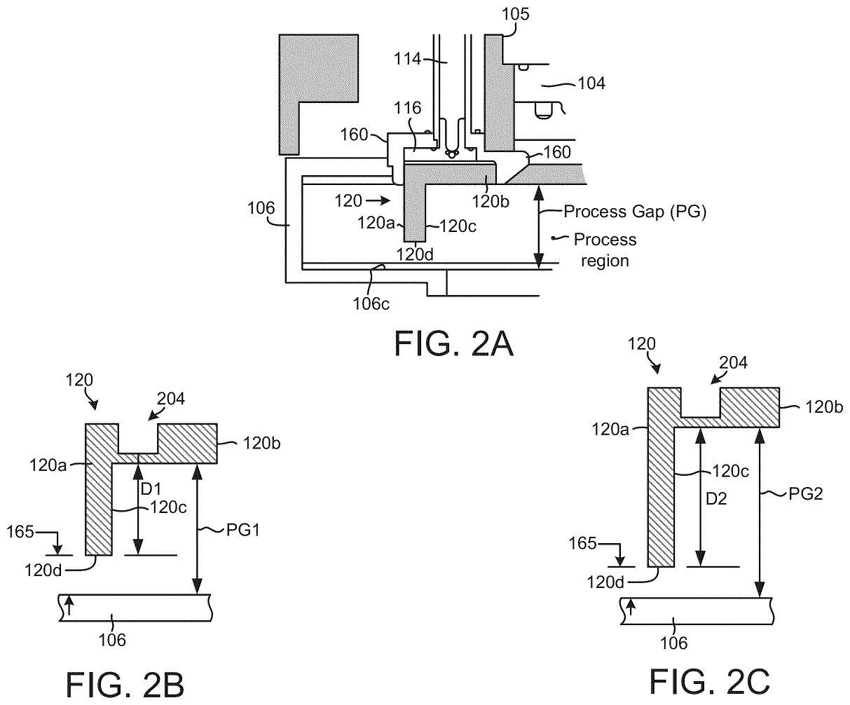

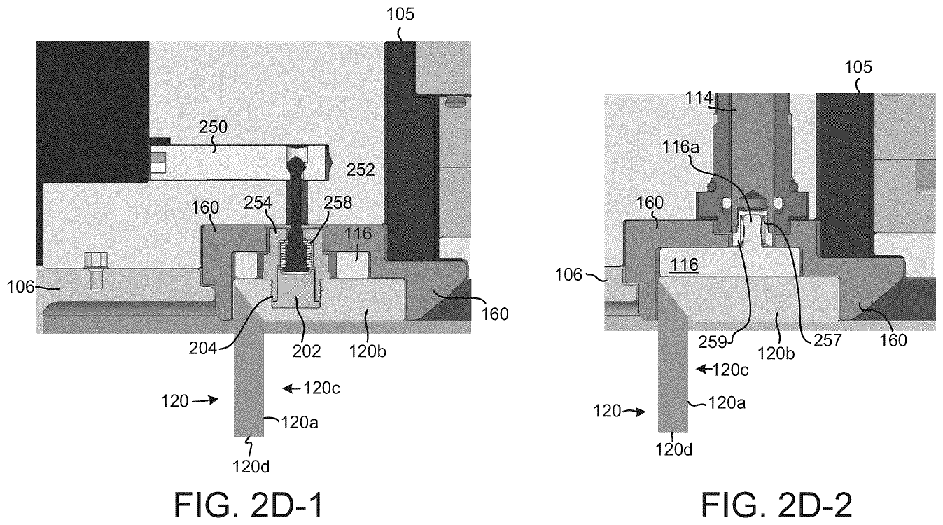

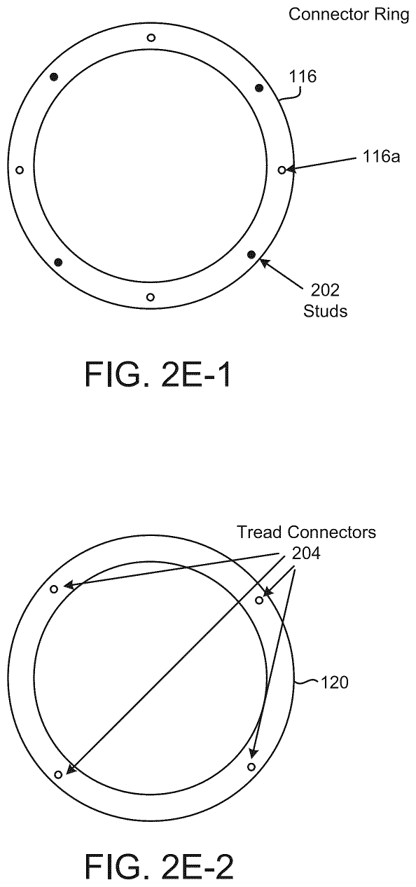

FIG. 2A illustrates a more detailed view of the outer upper electrode 120. As shown, the outer upper electrode 120 includes the vertical section 120a, the horizontal section 120b, the inner facing surface 120c and the lower end 120d. The connector ring 116 is electrically connected and fastened to the horizontal section 120a, and an electrode insulator 160 surrounds the connector ring 116 and part of the horizontal section 120a. The connector ring 116 is connected to each of the power rods 114. Insulator 105 insulates portions of the upper electrode 104 from regions of the electrode insulator 160 and other chamber parts.

FIGS. 2B and 2C illustrate cross-sectional views of the outer upper electrode 120, which cross-section is illustrated as an L-shape. The outer upper electrode 120 is therefore an annular structure that includes the horizontal section 120b and the vertical section 120a. In some configurations, a threaded connection 204 is defined on an upper surface of the horizontal section 120b for attaching the outer upper electrode 120 electrically to the connector ring 116. The threaded connection 204 is shown in a cross-sectional view, and in one embodiment, multiple threaded connections 204 can be provided to secure the outer upper electrode 122 the connector ring 116. In one embodiment, there are four connections made to the threaded connection 204 to secure the connector ring 116 to the outer upper electrode 120. The configuration of FIG. 2B illustrates an embodiment where the vertical section 120a has a dimension D1 that is shorter than dimension D2 of FIG. 2C. In FIG. 2B, the process gap PG1 may range between about 48 mm and 58 mm. In FIG. 2C, the process gap PG2 may range between about 68 mm and 78 mm. Depending on the configuration required for a process recipe, the length dimension D1 or D2 of the vertical section 120a can be modified. By way of example, in FIG. 2B D1 may be about 23 mm and in FIG. 2C D2 may be about 43 mm. In each of these configurations, the gap 165 may be between about 5 mm and about 20 mm, and in other configurations, the gap 165 may be between about 10 mm and about 15 mm, and in another embodiment, the gap 165 may be about 13 mm. The gap 165 is designed to provide a pathway for gases and materials produced in the process region during plasma processing to be removed in a controlled manner. In some embodiments, the dimension of the gap 165 provides for sufficient gas flows out through the C-shroud 106, but at the same time provides enough surface area on the inner facing surface 120c of the vertical section 120a to produce a plasma sheath and provide for generation of secondary electrons parallel to and over the wafer.

By way of example, the gas flow will be allowed to flow through the gap 165 around the perimeter of the plasma 180 region and then flow out through the plurality of slots 106a of the C-shroud 106. By setting the gap 165 to be in the desired separation range, it is possible to throttle the gas flow and affect plasma density during processing and generation of plasma 180 in the process region between the upper electrode 104, the lower electrode 102, and the outer upper electrode 120.

In one embodiment, the outer upper electrode 120 is configured to be connected to the RF source or DC source 172, which provides for the separate generation of a plasma sheath proximate to the inner facing surface 120c of the outer upper electrode 120. As mentioned above, generating a plasma sheath proximate to the inner facing surface 120c, it is possible to generate transverse electron beams that further enable increases in power efficiency and/or density, and chemistry control and uniformity control of etching over the wafer. As mentioned above, in one embodiment, power is provided to the outer upper electrode 120 (using a DC source or an RF source), which provides for a separate plasma sheath from the plasma sheath that is generated between the upper electrode 104 and the lower electrode 102.

In one embodiment, secondary electrons are accelerated in the high voltage 400 kHz or DC sheath inner facing surface 120c of the vertical section 120a, which will travel across plasma 180 increasing efficiency of RF discharge.

In another embodiment, the outer upper electrode 120 is powered (using a DC source or an RF source) to produce the transverse electron beams as a main RF power to create low ion energy plasma at wafer for ALD/ALE applications. In this configuration, it is envisioned that the upper electrode 104 and the lower electrode 102 are not powered, and may be coupled to ground.

In one embodiment, the surface edges of the vertical section 120a at and around the lower end 120d will have slightly rounded or non-sharp geometries. By way of example, the rounded edges will have a radii range of about 0.5 to about 2 mm. In another embodiment, the radii range will be about 1.0 to about 1.5 mm.

FIG. 2D-1 illustrates a closer view of the connection between the connector ring 116 and the outer upper electrode 120. In this example, a supporting bracket 250 is connected to a rod 252. The rod 252 is coupled to studs 202, and a spring 258 is compressed in ring 254. This structure provides one example way of clamping together the connector ring 116 and the outer upper electrode 120 within electrode insulator 160.

FIG. 2D-2 illustrates a closer view of the connection between the connector ring 116 and the power rod 114, which provides power to the outer upper electrode 120 via the connector ring 116. As shown, the connector ring 116 includes a plurality of protrusions 116a that correspondingly coupled to each of the plurality of power rods 114. A spring 259 is shown providing electrical contact between the protrusion 116a and a threaded end 257 of the power rod 114.

FIG. 2E-1 illustrates a top view of connector ring 116 having four protrusions 116a for connecting to the power rods 114. Also shown are studs 202 passing through the connector ring 116 for attaching to threaded connections 204. The connector ring 116 is configured to sit over the outer upper electrode 120 when installed, as shown in FIGS. 2D-1 and 2D-2.

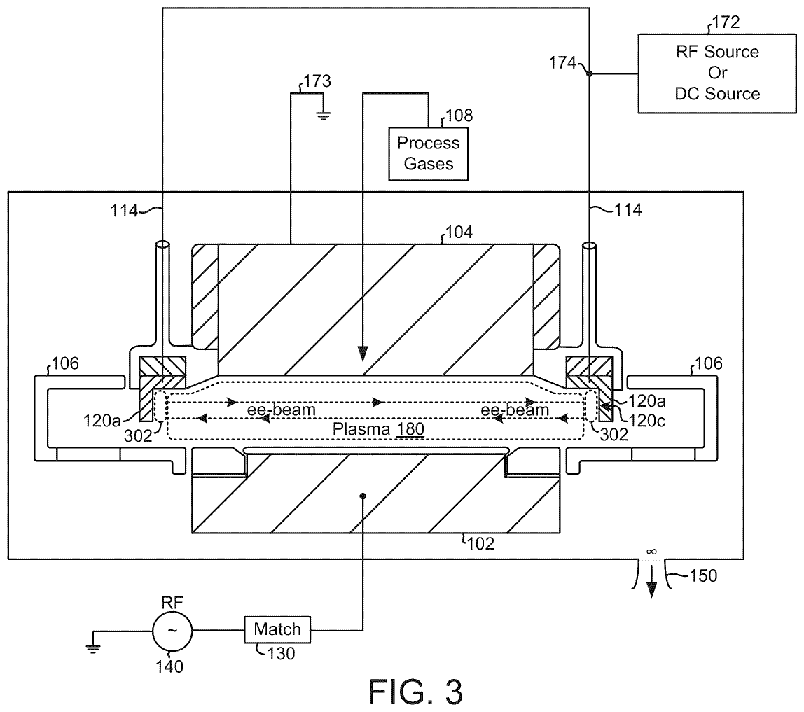

FIG. 3 illustrates the example configuration of a semiconductor processing chamber having the outer upper electrode 120 with the vertical section 120a. As discussed above, when the power rods 114 are provided with power through connection node 174, secondary electrons are accelerated in the high voltage 400 kHz or DC sheath 302 at the inner facing surface 120c of the vertical section 120a. The secondary electrons will travel across plasma 180 increasing efficiency of RF discharge. In this configuration, RF power can also be provided through RF source 140 and match 130, while the upper electrode 104 is coupled to ground 173.

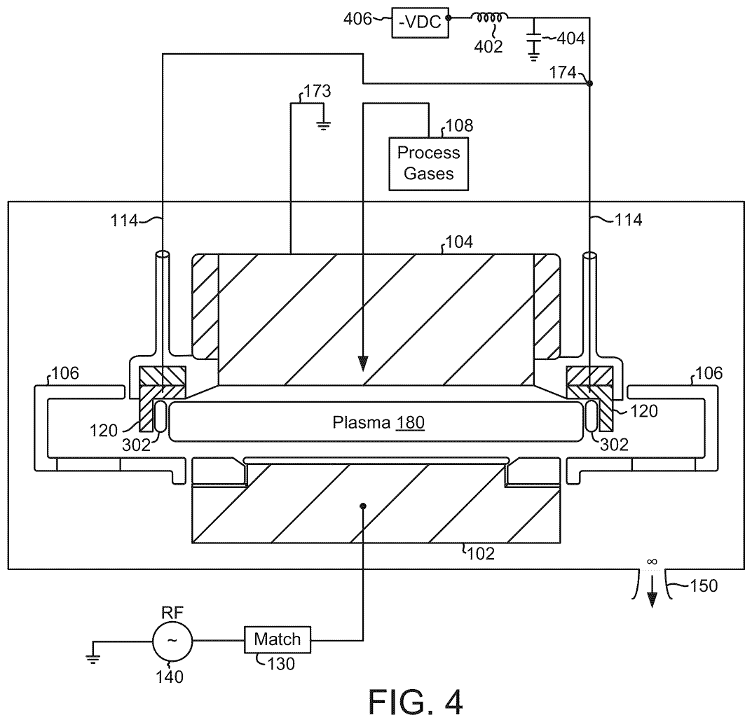

FIG. 4 illustrates an embodiment where a direct current (DC) voltage source 406 is coupled to the connection node 174, for providing DC power to the outer upper electrode 120. In this configuration, a filter circuit defined by an inductor 402 and capacitor 404 is also provided at the output of the DC voltage source 406 and input of the connection node 174. In one example, the capacitor 404 is a low frequency filter capacitor (about 9.6 nF) and the inductor 402 is a high frequency filter inductor (about 2.5 uH). These values can be adjusted, and are only provided as one example.

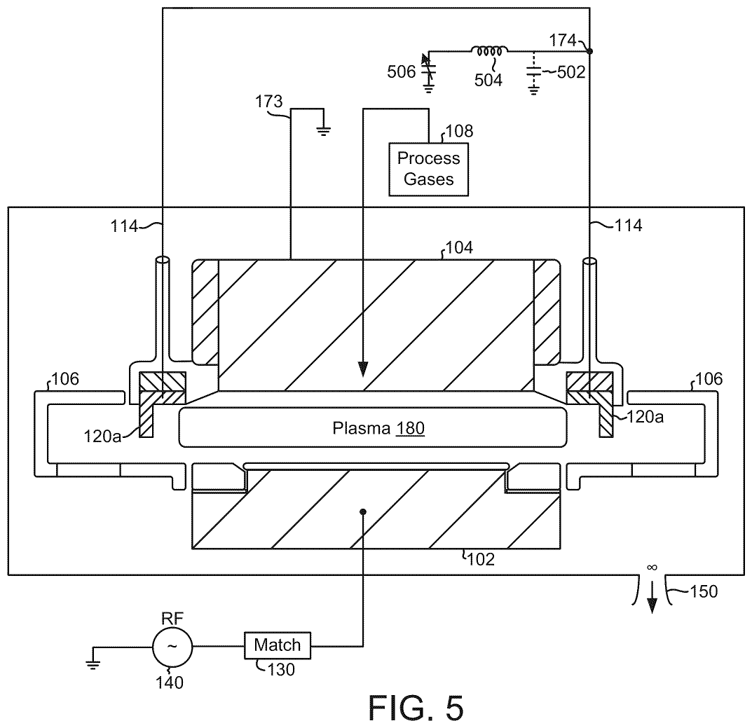

FIG. 5 illustrates an embodiment where a filter circuit is connected to the connection node 174, and no power source is connected to the connection node 174. In this embodiment, the filter circuit includes an inductor 504, and a variable capacitor 506. Stray capacitance 502 is also produced. In this configuration, power is delivered by an RF generator 140 via a match 130, which is connected to the lower electrode 102. The upper electrode 104 is connected to ground 173. The inductor 504 is a result of a strap, and the capacitor 506 may be set between about 5 pF and about 125 pF. This configuration and adjustments to the variable capacitor 506 have been shown to provide additional adjustability to the uniformity profile of the etch rate across the surface of the wafer.

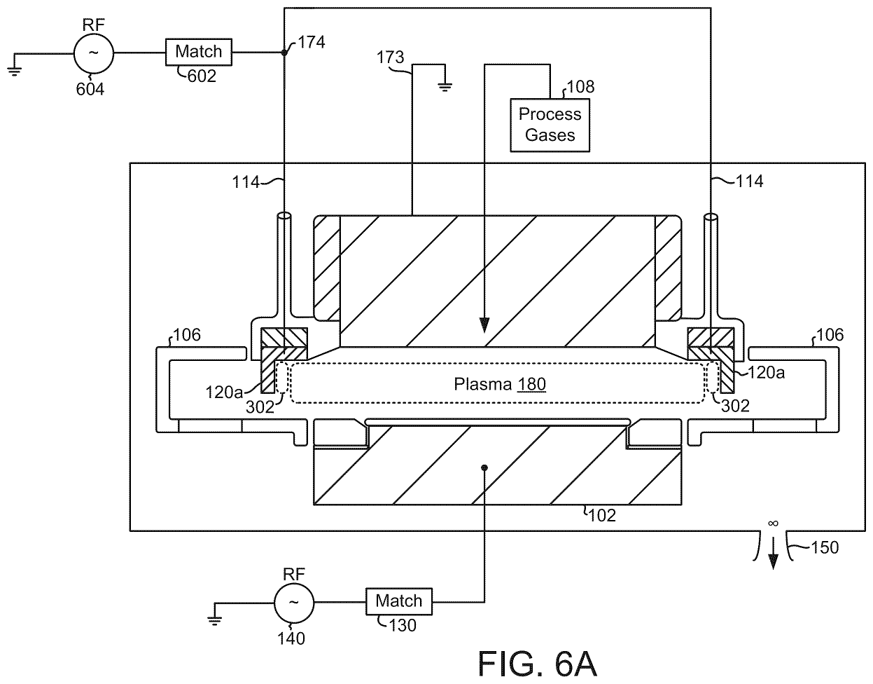

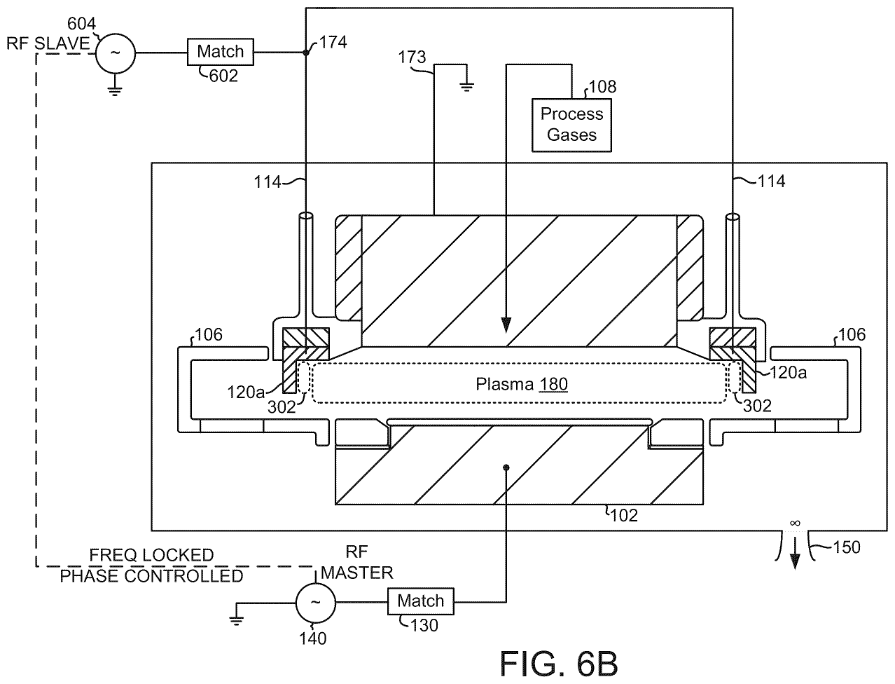

FIG. 6A illustrates an embodiment where connection node 174 is coupled to an RF source 604 and match 602, for providing RF power to the outer upper electrode 120 via power rods 114. In this embodiment, the RF power source 604 may be a high voltage 400 kHz generator that produces a plasma sheath 302 along the vertical section. The plasma sheath 302 will therefore provide for the generation of secondary electrons that are accelerated in the transverse direction to increase the efficiency of RF discharge from the main plasma sheath. The main plasma sheath is produced between the upper electrode 104 and lower electrode 102, using the RF source 140 and match 130 connected to the lower electrode 102.

FIG. 6B illustrates an embodiment where the RF source 604 and the RF source 140 are frequency locked and phase controlled. A controller of the plasma processing system will make the connection between the RF generators, wherein our source 604 operates as a slave RF generator and the RF source 140 operates as a master RF generator. In some embodiments, one or both of the RF generators 604 and 140 may be operated in a pulsing mode, depending on the process recipe being used.

In one embodiment, the source 604 is a slave RF source, and the source 140 is a master RF source. The master RF source may be configured to operate at a first frequency and the slave RF source may be configured to operate at a second frequency. In some configurations, the second frequency of the slave RF source may be the same as the first frequency or a harmonic of the first frequency. In some configurations, the first frequency may have a first phase and the second frequency may have a second phase. In one embodiment, the second phase may be phased locked to the second phase. Generally, in some embodiments, the master and the slave may have the same frequency, phase controlled and locked, and voltage or power controlled slave generator.

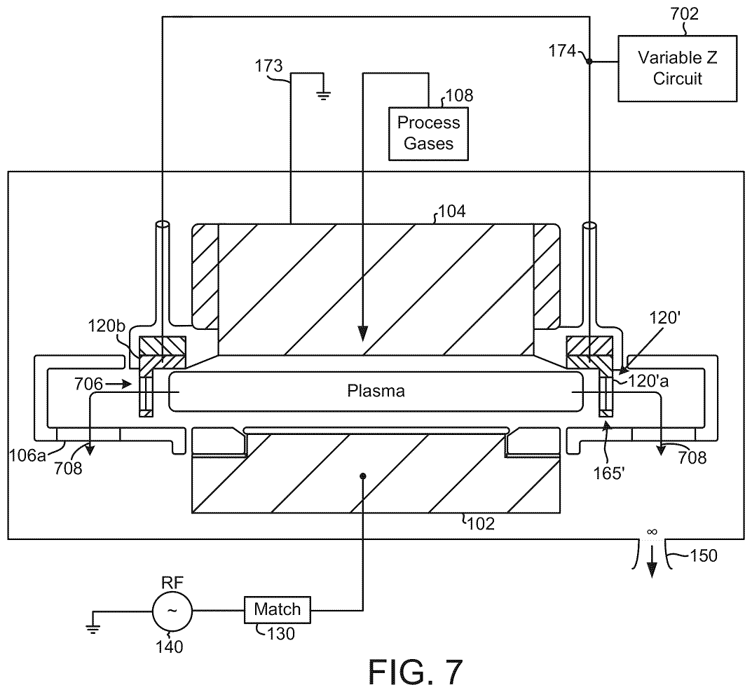

FIG. 7 illustrates an embodiment where connection node 174 is connected to a variable impedance circuit 702. In this embodiment, by modifying the impedance supplied to the outer upper electrode 120, it is possible to affect the shape and density of the plasma 180 in the plasma processing region between the upper electrode 104 and the lower electrode 102. Thus, by adjusting the variable impedance circuit 702, an additional knob is provided to a process engineer to tune the efficiency, profile and effectiveness of a plasma operation. This control is also possible using any of the above example configurations that provide power to the outer upper electrode 120, whether it is by applying RF power, DC power, filters using inductors and/or capacitors, or the like, connected to the connection node 174.

FIG. 7 also shows an alternative embodiment of outer upper electrode 120′, which includes a vertical section 120a′ with a plurality of slots 706. The slots are arranged around the vertical section 120a′, since the vertical section 102a′ is an annular section that connects to the horizontal section 120b. By providing a plurality of slots 706 in the vertical section 120a′, it is possible to reduce the gap 165′ to between about 1 mm to about 3 mm. This separation provided by gap 165′, since it is reduced, provides for a majority of the gas flow to be channeled out through the plurality of slots 706 formed in the vertical section 120a′. The gas flow is then channeled out of the slots 106a of the shroud 106.

In one alternative configuration, it is possible to operate the system as an edge radical control plasma (RCP) system. In an edge RCP configuration, a plasma is generated by supplying power to the outer upper electrode 120′, e.g., using a 60 MHz frequency generator. When a plasma is generated, the slots 706 (or holes) in the vertical section 120a′ enable a flux of neutrals and electrons to be transferred into the process area between the upper electrode 104 and lower electrode 102 where the wafer is located.

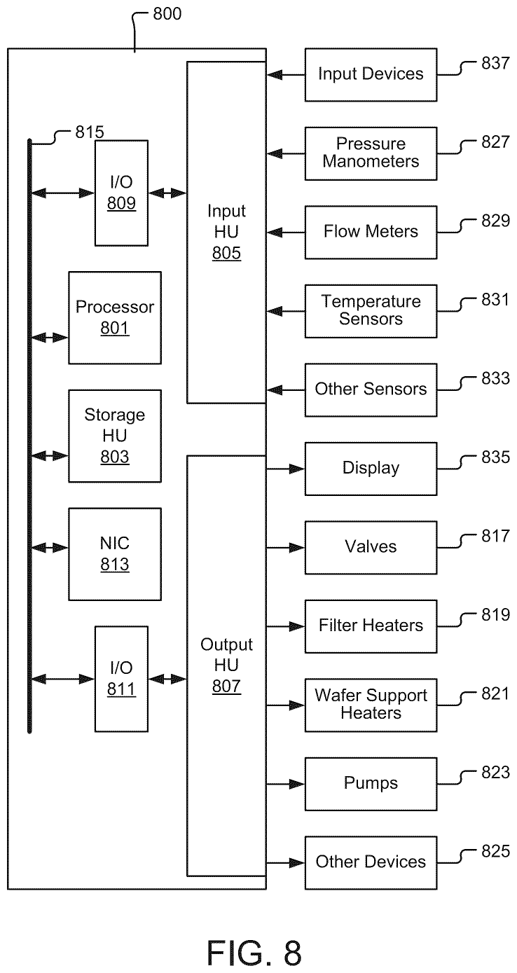

FIG. 8 shows an example schematic of the control system 800 for controlling and/or operating semiconductor processing system 100, in accordance with some embodiments. In some embodiments, the control system 800 is configured as a process controller for controlling the semiconductor fabrication process performed in processing system 100. In various embodiments, the control system 800 includes a processor 801, a storage hardware unit (HU) 803 (e.g., memory), an input HU 805, an output HU 807, an input/output (I/O) interface 809, an I/O interface 811, a network interface controller (NIC) 813, and a data communication bus 815. The processor 801, the storage HU 803, the input HU 805, the output HU 807, the I/O interface 809, the I/O interface 811, and the NIC 813 are in data communication with each other by way of the data communication bus 815. The input HU 805 is configured to receive data communication from a number of external devices. Examples of the input HU 805 include a data acquisition system, a data acquisition card, etc. The output HU 807 is configured to transmit data to a number of external devices. An example of the output HU 807 is a device controller. Examples of the NIC 813 include a network interface card, a network adapter, etc. Each of the I/O interfaces 809 and 811 is defined to provide compatibility between different hardware units coupled to the I/O interface. For example, the I/O interface 809 can be defined to convert a signal received from the input HU 805 into a form, amplitude, and/or speed compatible with the data communication bus 815. Also, the I/O interface 807 can be defined to convert a signal received from the data communication bus 815 into a form, amplitude, and/or speed compatible with the output HU 807. Although various operations are described herein as being performed by the processor 801 of the control system 800, it should be understood that in some embodiments various operations can be performed by multiple processors of the control system 800 and/or by multiple processors of multiple computing systems in data communication with the control system 800.

In some embodiments, the control system 800 is employed to control devices in various wafer fabrication systems based in-part on sensed values. For example, the control system 800 may control one or more of valves 817, filter heaters 819, wafer support structure heaters 821, pumps 823, and other devices 825 based on the sensed values and other control parameters. The valves 817 can include valves associated with control of the backside gas supply system, the process gas supply system, and the temperature control fluid circulation system. The control system 800 receives the sensed values from, for example, pressure manometers 827, flow meters 829, temperature sensors 831, and/or other sensors 833, e.g., voltage sensors, current sensors, etc. The control system 800 may also be employed to control process conditions within the plasma processing system 100 during performance of plasma processing operations on the wafer W. For example, the control system 800 can control the type and amounts of process gas(es) supplied from the process gas supply system 108 to the plasma processing volume between the upper electrode 104 and lower electrode 102. Also, the control system 800 can control operation of the radiofrequency signal generator 140, the radiofrequency signal generator 604, and the impedance matching system 130 and 602. The control system 800 can also control operation of the lifting devices for the lift pins and operation of doors.

In some embodiments, the control system 800 is configured to execute computer programs including sets of instructions for controlling process timing, process gas delivery system temperature, and pressure differentials, valve positions, mixture of process gases, process gas flow rate, backside cooling gas flow rate, chamber pressure, chamber temperature, wafer support structure temperature (wafer temperature), RF power levels, RF frequencies, RF pulsing, impedance matching system settings, cantilever arm assembly position, bias power, and other parameters of a particular process. Other computer programs stored on memory devices associated with the control system 800 may be employed in some embodiments. In some embodiments, there is a user interface associated with the control system 800. The user interface includes a display 835 (e.g., a display screen and/or graphical software displays of the apparatus and/or process conditions), and user input devices 837 such as pointing devices, keyboards, touch screens, microphones, etc.

Software for directing operation of the control system 800 may be designed or configured in many different ways. Computer programs for directing operation of the control system 800 to execute various wafer fabrication processes in a process sequence can be written in any conventional computer readable programming language: for example, assembly language, C, C++, Pascal, Fortran or others. Compiled object code or script is executed by the processor 801 to perform the tasks identified in the program. The control system 800 can be programmed to control various process control parameters related to process conditions such as, for example, filter pressure differentials, process gas composition and flow rates, backside cooling gas composition and flow rates, temperature, pressure, plasma conditions, such as RF power levels and RF frequencies, bias voltage, cooling gas/fluid pressure, and chamber wall temperature, among others. Examples of sensors that may be monitored during the wafer fabrication process include, but are not limited to, mass flow control modules, pressure sensors, such as the pressure manometers 827 and the temperature sensors 831. Appropriately programmed feedback and control algorithms may be used with data from these sensors to control/adjust one or more process control parameters to maintain desired process conditions.

In some implementations, the control system 800 is part of a broader fabrication control system. Such fabrication control systems can include semiconductor processing equipment, including a processing tool, chambers, and/or platforms for wafer processing, and/or specific processing components, such as a wafer pedestal, a gas flow system, etc. These fabrication control systems may be integrated with electronics for controlling their operation before, during, and after processing of the wafer. The control system 800 may control various components or subparts of the fabrication control system. The control system 800, depending on the wafer processing requirements, may be programmed to control any of the processes disclosed herein, including the delivery of processing gases, the delivery of backside cooling gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the control system 800 may be defined as electronics having various integrated circuits, logic, memory, and/or software that receive instructions, issue instructions, control operation, enable wafer processing operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the control system 800 in the form of various individual settings (or program files), defining operational parameters for carrying out a particular process on the wafer W within system 100. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The control system 800, in some implementations, may be a part of or coupled to a computer that is integrated with, coupled to the plasma processing system 100, or otherwise networked to the system 100, or a combination thereof. For example, the control system 800 may be in the “cloud” of all or a part of a fab host computer system, which can allow for remote access of the wafer processing. The computer may enable remote access to the system 100 to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to the system 100 over a network, which may include a local network or the Internet.

The remote computer may include a user interface that enables entry or programming of parameters and/or settings, which are then communicated to the system 100 from the remote computer. In some examples, the control system 800 receives instructions in the form of data, which specify parameters for each of the processing steps to be performed during one or more operations. It should be understood that the parameters may be specific to the type of process to be performed within the plasma processing system 100. Thus, as described above, the control system 800 may be distributed, such as by comprising one or more discrete controllers that are networked together and working towards a common purpose, such as the processes and controls described herein. An example of a distributed controller for such purposes would be one or more integrated circuits on the plasma processing system 100 in communication with one or more integrated circuits located remotely (such as at the platform level or as part of a remote computer) that combine to control a process performed on the plasma processing system 100.

Without limitation, example systems that the control system 800 can interface with may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers. As noted above, depending on the process step or steps to be performed by the tool, the control system 800 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Embodiments described herein may also be implemented in conjunction with various computer system configurations including hand-held hardware units, microprocessor systems, microprocessor-based or programmable consumer electronics, minicomputers, mainframe computers and the like. Embodiments described herein can also be implemented in conjunction with distributed computing environments where tasks are performed by remote processing hardware units that are linked through a network. It should be understood that the embodiments described herein, particularly those associated with the control system 800, can employ various computer-implemented operations involving data stored in computer systems. These operations are those requiring physical manipulation of physical quantities. Any of the operations described herein that form part of the embodiments are useful machine operations. The embodiments also relate to a hardware unit or an apparatus for performing these operations. The apparatus may be specially constructed for a special purpose computer. When defined as a special purpose computer, the computer can also perform other processing, program execution or routines that are not part of the special purpose, while still being capable of operating for the special purpose. In some embodiments, the operations may be processed by a general purpose computer selectively activated or configured by one or more computer programs stored in the computer memory, cache, or obtained over a network. When data is obtained over a network, the data may be processed by other computers on the network, e.g., a cloud of computing resources.

Various embodiments described herein can be implemented through process control instructions instantiated as computer-readable code on a non-transitory computer-readable medium. The non-transitory computer-readable medium is any data storage hardware unit that can store data, which can thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes, and other optical and non-optical data storage hardware units. The non-transitory computer-readable medium can include computer-readable tangible medium distributed over a network-coupled computer system so that the computer-readable code is stored and executed in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

What is claimed is:

1. A capacitively coupled plasma (CCP) chamber, comprising:
a lower electrode;
an upper electrode;
an outer upper electrode arranged to surround the upper electrode, the outer upper electrode includes a horizontal section and a vertical section, the vertical section being substantially perpendicular to a surface of the upper electrode that is arranged to face the lower electrode; and
a shroud arranged to surround a process space between the upper electrode and the lower electrode,
wherein the vertical section has an inner surface that faces and surrounds the process space.

2. The capacitively coupled plasma (CCP) chamber of claim 1, wherein the horizontal section is integral with the vertical section to form an L-shape.

3. The capacitively coupled plasma (CCP) chamber of claim 1, wherein the shroud has a lower horizontal section, a side vertical section, and an upper horizontal section, the lower horizontal section includes a plurality of slots.

4. The capacitively coupled plasma (CCP) chamber of claim 3, wherein the vertical section of the outer upper electrode extends downwardly from the horizontal section, a lower end of the vertical section is spaced apart by a gap from the lower horizontal section of the shroud.

5. The capacitively coupled plasma (CCP) chamber of claim 1, further comprising,
a connector ring coupled to the horizontal section of the outer upper electrode, the connector ring is electrically attached to the horizontal section and provides for connections for a plurality of power rods, the plurality of power rods are coupled to one of an RF power source, or a DC power source, or ground.

6. The capacitively coupled plasma (CCP) chamber of claim 1, wherein the outer upper electrode is electrically connected to one of an RF power source, or a DC power source, or ground, the lower electrode is connected to the RF power source, and the upper electrode is connected to ground.

7. The capacitively coupled plasma (CCP) chamber of claim 1, wherein the vertical section includes a plurality of slots.

8. The capacitively coupled plasma (CCP) chamber of claim 1, wherein the horizontal section of the outer upper electrode is connected to a plurality of rods, and each of the plurality of rods are electrically coupled to provide a connection a connection node to the outer upper electrode.

9. The capacitively coupled plasma (CCP) chamber of claim 8, wherein the connection node is coupled to a filter, a DC power supply, an RF power supply, or a filter and DC power supply, or variable impedance circuit.

10. The capacitively coupled plasma (CCP) chamber of claim 8, wherein the connection node is connected to a filter that includes a parallel capacitor and inductor coupled to a direct current (DC) voltage source.

11. The capacitively coupled plasma (CCP) chamber of claim 8, wherein the connection node is connected to a filter that includes a series variable capacitor and series inductor.

12. The capacitively coupled plasma (CCP) chamber of claim 8, wherein the connection node is coupled to a slave RF source and the lower electrode is coupled to a master RF source, the master RF source and the slave RF source are frequency locked and phase controlled.

13. An outer upper electrode for a capacitively coupled plasma (CCP) chamber, comprising:
the outer upper electrode is configured to surround an upper electrode of the CCP chamber, the outer upper electrode includes a horizontal section and a vertical section, the vertical section is substantially perpendicular to a surface of the upper electrode that faces a lower electrode of the CCP chamber;
wherein the vertical section has an inner surface that faces and surrounds a process space.

14. The outer upper electrode of claim 13, wherein the horizontal section is integral with the vertical section to form an L-shape.

15. The outer upper electrode of claim 13, wherein the vertical section extends downwardly from the horizontal section, and a lower end of the vertical section is spaced apart by a gap from a lower surface.

16. The outer upper electrode of claim 15, wherein a C-shroud is configured to surround a process space between the upper electrode and lower electrode of the CCP chamber, wherein the lower surface is part of a lower horizontal section of the C-shroud, and the lower horizontal section of the C-shroud includes a plurality of slots.

17. The outer upper electrode of claim 13, further comprising,
a connector ring coupled to the horizontal section of the outer upper electrode, the connector ring is electrically attached to the outer upper electrode and provides for connections for a plurality of power rods, the plurality of power rods are electrically coupled to a connection node that connects to one of an RF power source, or a DC power source, or ground.

18. The outer upper electrode of claim 13, wherein the vertical section includes a plurality of slots.

19. The outer upper electrode of claim 13, wherein the horizontal section of the outer upper electrode is connected to a plurality of rods, and each of the plurality of rods are electrically coupled to provide a connection node to the outer upper electrode;
wherein the connection node is coupled to a filter, a DC power supply, an RF power supply, or a filter and DC power supply, or variable impedance circuit; or
wherein the connection node is connected to a filter that includes a parallel capacitor and inductor coupled to a direct current (DC) voltage source; or
wherein the connection node is connected to a filter that includes a series variable capacitor and series inductor.

20. The outer upper electrode of claim 13, wherein the outer upper electrode is connected to a plurality of power rods, the plurality of power rods are electrically coupled to a connection node that is coupled to a slave RF source, and the lower electrode is coupled to a master RF source, the master RF source and the slave RF source are frequency locked and phase controlled.

21. The outer upper electrode of claim 13, wherein the outer upper electrode is connected to a plurality of power rods, the plurality of power rods are electrically coupled to a connection node that is coupled to a slave RF source, and the lower electrode is coupled to a master RF source, and wherein a second frequency of the slave RF source is a harmonic of a first frequency of the master RF source, and a second phase of the second frequency is phase locked to a first phase of the first frequency.
